(19) United States
(12) Patent Application Publication
(10) Pub. No.: US 2018/0315626 A1
(43) Pub. Date: Nov. 1, 2018

(54) HIGH PRESSURE ANNEAL CHAMBER WITH VACUUM ISOLATION AND PRE-PROCESSING ENVIRONMENT

(71) Applicant: Applied Materials, Inc., Santa Clara, CA (US)

(72) Inventor: Timothy J. FRANKLIN, Campbell, CA (US)

(21) Appl. No.: 15/964,300

(22) Filed: Apr. 27, 2018

Related U.S. Application Data
(60) Provisional application No. 62/492,700, filed on May 1, 2017.

(51) Int. Cl. H01L 21/67; H01L 21/762; H01L 21/687; H01L 21/677; C23C 16/44; C23C 16/458; C23C 16/452; F16J 15/06; F16J 15/00

(52) U.S. Cl. CPC H01L 21/67103; H01L 21/76224; H01L 21/68742; H01L 21/67757; H01L 21/67109; F16J 15/002; C23C 16/458; C23C 16/4411; C23C 16/452; F16J 15/06; C23C 16/4409

(57) ABSTRACT

Embodiments of the disclosure generally relate to a method and apparatus for filling gaps and trenches on a substrate and tools for batch annealing substrates. In one embodiment, a batch processing chamber comprising a lower shell, a substrate transfer port formed through the lower shell, an upper shell disposed on the lower shell, an inner shell disposed within the upper shell, a heater operational to heat the inner shell, a lift plate moveably disposed within the lower shell, a cassette disposed on the lift plate and configured to hold a plurality of substrates within the inner chamber, and an injection port, is disclosed. The inner shell and upper shell bound an outer chamber while the inner shell and the lower shell bound an inner chamber that is partially enveloped by the outer chamber. The injection port is configured to introduce a fluid into the inner chamber.

### CROSS-REFERENCE TO RELATED APPLICATIONS

This application claims benefit of U.S. provisional patent application Ser. No. 62/492,700, filed May 1, 2017, which is herein incorporated by reference.

### BACKGROUND

### Field

Embodiments of the disclosure generally relate to a method and apparatus for filling gaps and trenches on a substrate and tools for batch annealing substrates.

### Description of the Related Art

Semiconductor device geometries have dramatically decreased in size since their introduction several decades ago. Increasing device densities have resulted in structural features having decreased spatial dimensions. The aspect ratio (ratio of depth to width) of gaps and trenches forming the structural features of modern semiconductor devices have narrowed to a point where filling the gap with material has become extremely challenging. A significant contributor to this challenge is the propensity of material deposited in the gap to be prone to clogging at the opening of the gap before the gap is completely filled.

Thus, there is need for an improved apparatus and method for filling high-aspect-ratio gaps and trenches on a substrate.

### SUMMARY

Embodiments of the disclosure generally relate to a method and apparatus for filling gaps and trenches on a substrate and tools for batch annealing substrates. In one embodiment, a batch processing chamber is disclosed. The batch processing chamber includes a lower shell, a substrate transfer port formed through the lower shell, an upper shell disposed on the lower shell, an inner shell disposed within the upper shell, a heater operational to heat the inner shell, a lift plate moveably disposed within the lower shell, a cassette disposed on the lift plate and configured to hold a plurality of substrates within the inner chamber, and an injection port. The inner shell and upper shell bound an outer chamber while the inner shell and the lower shell bound an inner chamber that is isolated from the outer chamber. The injection port is configured to introduce a fluid into the inner chamber.

In another embodiment of the disclosure, a batch processing chamber is disclosed. The batch processing chamber includes a lower shell, a substrate transfer port formed through the lower shell, a bottom plate coupled to a bottom surface of the lower shell, an upper shell disposed on the lower shell, an inner shell disposed within the upper shell, an outer chamber bounded by the inner shell and the upper shell, one or more heaters disposed within the outer chamber, a lift plate moveably disposed within the lower shell, a heating element coupled to the lift plate, a cassette disposed on the lift plate and configured to hold a plurality of substrates, an injection ring removably coupled to a bottom surface of the inner shell, an injection port disposed within the injection ring, a high-pressure seal configured to couple the injection ring to the lift plate, a cooling channel disposed adjacent to the high-pressure seal, one or more outlet ports formed through the injection ring and a remote plasma source. The inner shell bounds a portion of an inner chamber having a high-pressure region and a low-pressure region. The outer chamber is isolated from the inner chamber. The one or more heaters disposed within the outer chamber are operational to heat the inner shell. The lift plate is configured to be raised to seal the high-pressure region and lowered to allow fluid communication between the high-pressure region and the low-pressure region. The injection port disposed within the injection ring is configured to introduce a fluid into the inner chamber. The high-pressure seal is configured to couple the injection ring to the lift plate in the high-pressure region. The one or more outlet ports face the injection port across the inner chamber. The remote plasma source is coupled to the inner chamber.

In yet another embodiment of the disclosure, a method for processing a plurality of substrates disposed in a batch processing chamber is disclosed. The method includes loading a cassette disposed on a lift plate with a plurality of substrates, wherein the cassette and the lift plate are disposed in an inner chamber of the batch processing chamber such that at least a first substrate of the plurality of substrates having a flowable material is exposed on an exterior surface of the substrate, elevating the cassette to a processing position that isolates the cassette in a high-pressure region of the inner chamber from a low-pressure region of the inner chamber and flowing the flowable material exposed on the exterior surface of the first substrate. The flowing of the flowable material is performed while pressurizing the high-pressure region to a pressure greater than about 50 bars, heating the first substrate to a temperature greater than about 450 degrees Celsius and exposing the first substrate to a processing fluid.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a simplified front cross-sectional view of the batch processing chamber with the cassette in the low-pressure region.

FIG. 2 is a simplified front cross-sectional view of the batch processing chamber with the cassette in the high-pressure region.

FIG. 3 is a simplified front cross-sectional view of the injection ring connected to the inner shell of the batch processing chamber.

FIG. 4 is a simplified front cross-sectional view of a cassette with a plurality of substrates disposed on a plurality of substrate storage slots.

FIG. 5 is a schematic view of a substrate prior to processing in the batch processing chamber.

FIG. 6 is a schematic view of a substrate after processing in the batch processing chamber.

FIG. 7 is a block diagram of a method for processing a plurality of substrates disposed in the batch processing chamber of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to a method and apparatus for filling gaps and trenches on a substrate and tools for batch annealing substrates that is particularly suitable for filling high-aspect-ratio gaps and trenches with flowable materials.

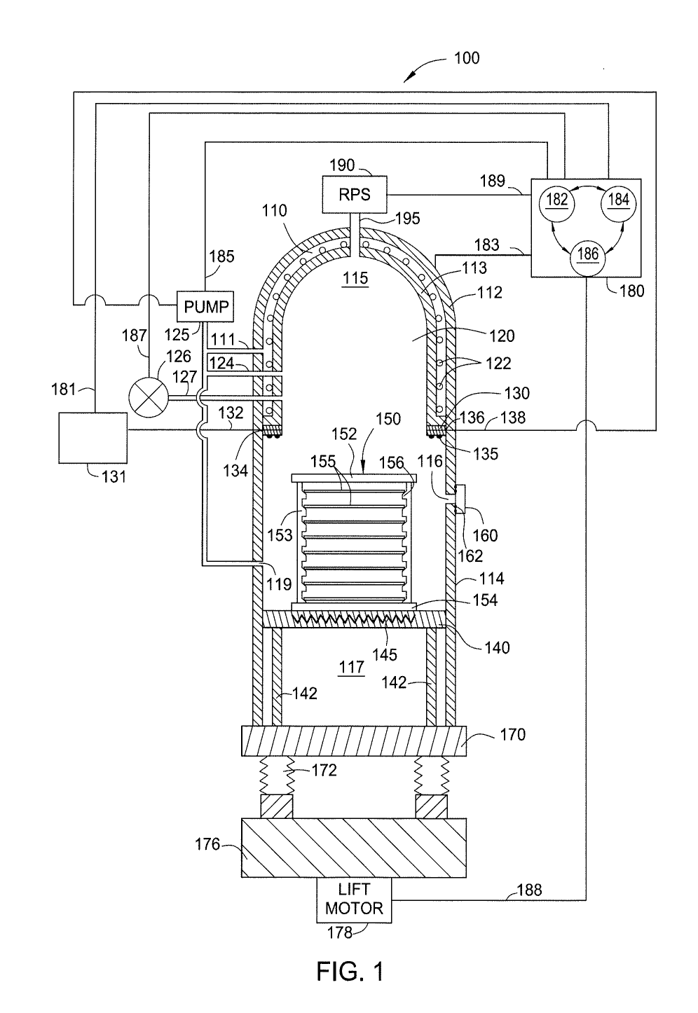

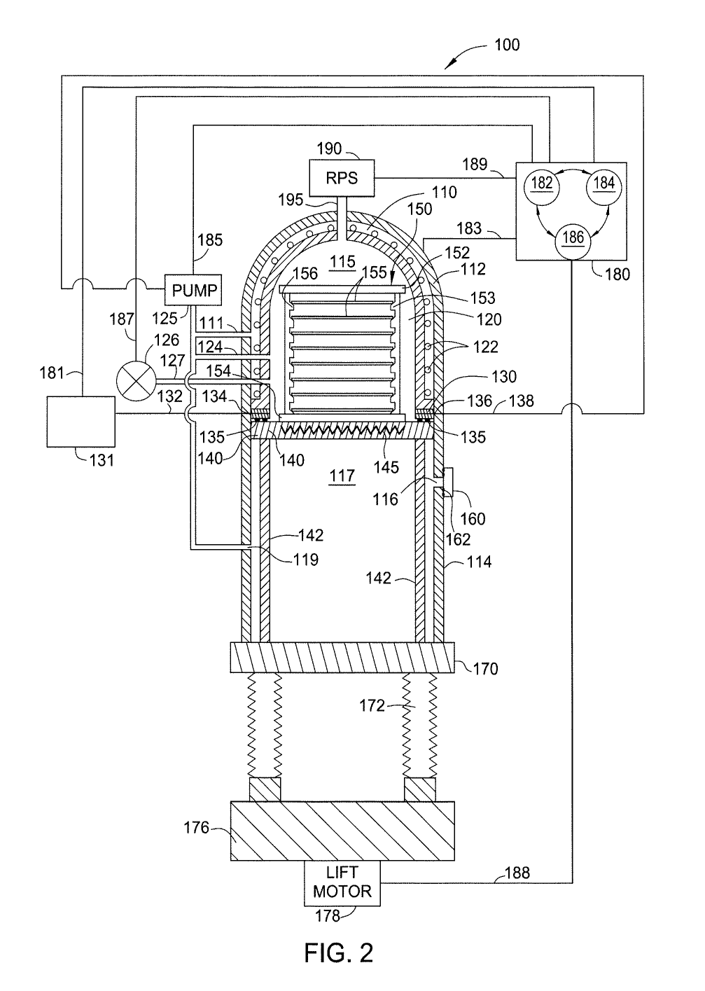

FIG. 1 is a simplified front cross-sectional view of the batch processing chamber. The batch processing chamber 100 has an upper shell 112 disposed on a lower shell 114. An inner shell 113 is disposed within the upper shell 112 such that an outer chamber 110 and an inner chamber 120 are formed. The inner shell 113 and the upper shell 112 bound the outer chamber 110. The inner shell 113 and the lower shell 114 bound the inner chamber 120. The outer chamber 110 is isolated from the inner chamber 120. A bottom plate 170 is coupled to the bottom surface of the lower shell 114. The inner chamber 120 has a high-pressure region 115 and a low-pressure region 117. The exteriors of the upper shell 112 and lower shell 114 may be made from a corrosion resistant steel (CRS), such as but not limited to stainless steel. The interiors of the inner shell 113, the upper shell 112 and the lower shell 114 as well as the bottom plate 170 may be made from nickel-based steel alloys that exhibit high resistance to corrosion, such as but not limited to HASTELLOY®.

One or more heaters 122 are disposed within the outer chamber 110. As further discussed below, the environment within the outer chamber 110 is maintained at a vacuum to improve the performance of the heaters 122. In the embodiment shown in FIG. 1, the heaters 122 are coupled to the inner shell 113. In other embodiments, the heaters 122 may be coupled to the upper shell 112. The heaters 122 are operable such that when the heaters 122 are turned on, the heaters 122 are able to heat the inner shell 113 and thus, also heat the high-pressure region 115 within the inner chamber 120. The heaters 122 may be a resistive coil, a lamp, a ceramic heater, a graphite-based carbon fiber composite (CFC) heater, a stainless steel heater or an aluminum heater. Power to the heaters 122 is controlled by a controller 180 through feedback received from sensors (not shown), monitoring the temperature of the inner chamber 120.

A lift plate 140 is disposed within the inner chamber 120. The lift plate 140 is supported by one or more rods 142 on the bottom plate 170 of the inner chamber 120. The bottom plate 170 is coupled to a platform 176 connected to a lifting mechanism 178. In some embodiments, the lifting mechanism 178 may be a lift motor or other suitable linear actuator. In the embodiment shown in FIG. 1, a bellows 172 is utilized to seal the platform 176 to the bottom plate 170. The bellows 172 is attached to the bottom plate 170 by a fastening mechanism, such as but not limited to the clamps. Thus, the lift plate 140 is coupled to the lifting mechanism 178 that raises and lowers the lift plate 140 within the inner chamber 120. The lifting mechanism 178 raises the lift plate 140 to seal the high-pressure region 115. The lift plate 140 and lifting mechanism 178 are configured to function against a high pressure, for example pressures of about 50 bars, which acts representatively downward in the high-pressure region 115 of the inner chamber 120 when the lift plate 140 is in a raised position. The lifting mechanism 178 lowers the lift plate 140 to allow fluid communication between the high-pressure region 115 and the low-pressure region 117, and to facilitate substrate transfer into and out of the batch processing chamber 100. The operation of the lifting mechanism 178 is controlled by the controller 180.

A heating element 145 is interfaced with the lift plate 140. The heating element 145 is operated to heat the high-pressure region 115 within the inner chamber 120 during processing as well as pre-processing. The heating element 145 may be a resistive coil, a lamp, or a ceramic heater. In the embodiment depicted in FIG. 1, the heating element 145 is a resistive heater coupled to or disposed in the lift plate 140. Power to the heating element 145 is controlled by the controller 180 through feedback received from sensors (not shown), monitoring the temperature of the inner chamber 120.

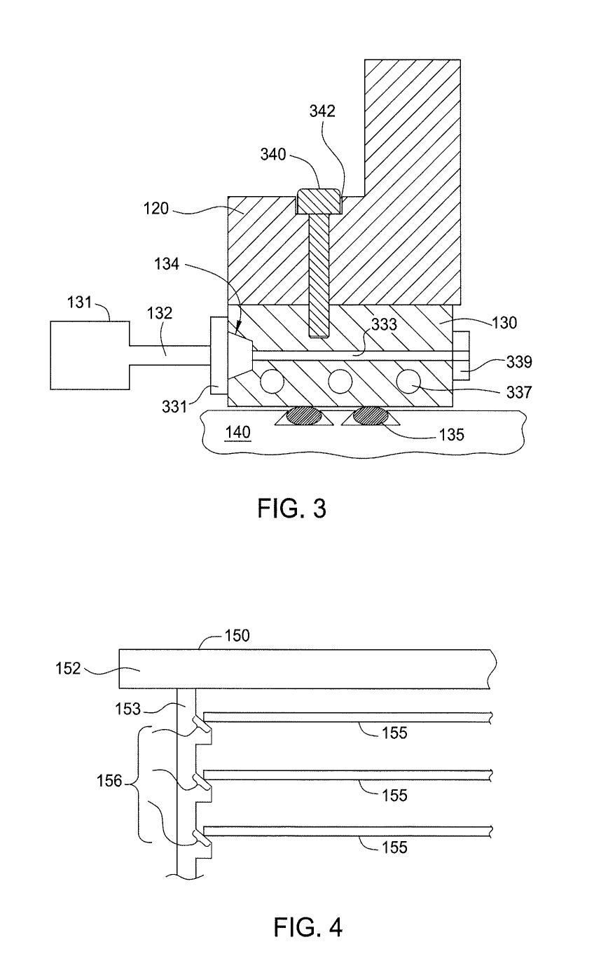

High-pressure seals 135 are utilized to seal the lift plate 140 to the inner shell 113 in order to seal the high-pressure region 115 for processing. The high-pressure seal 135 may be made from a polymer, such as but not limited to a perflouroelastomer. A cooling channel 337 (FIG. 3) is disposed adjacent to the high-pressure seals 135 in order to maintain the high-pressure seals 135 below the maximum safe-operating temperature of the high-pressure seals 135 during processing. A cooling agent, such as but not limited to an inert, dielectric, and high-performance heat transfer fluid, may be circulated within the cooling channel 337 to maintain the high-pressure seals 135 at a temperature to prevent degradation of the high-pressure seals 135, such as between about 250-275 degrees Celsius. The flow of the cooling agent within the cooling channel 337 is controlled by the controller 180 through feedback received from temperature and/or flow sensors (not shown).

The batch processing chamber 100 includes at least one injection port 134 and one or more outlet ports 136. The injection port 134 is configured to introduce a fluid into the inner chamber 120 while the one or more outlet ports 136 is configured to remove the fluid from the inner chamber 120. The injection port 134 and the one or more outlet ports 136 face each other across the inner chamber 120 to induce a cross flow across the substrates within the high-pressure region 115.

In some embodiments, the inner shell 113 may be coupled to an injection ring 130, shown in FIG. 3, that has a cylindrical annulus shape around the inner chamber 120. The injection ring 130 is removably coupled to a bottom surface of the inner shell 113. In the embodiment depicted in FIG. 3, the injection port 134 and the one or more outlet ports 136 are formed in the injection ring 130. The injection port 134 includes a passage 333 formed through to injection ring 130. A fitting 331 is coupled to the passage 333 to facilitate coupling the injection port 134 to a fluid source 131 via an inlet tube 132. A nozzle 339 is coupled to the end of the passage 333 on the inside wall of the injection ring 130 to provide the processing fluid to the inner chamber 120. The one or more outlet ports 136 are configured to remove any fluid in the inner chamber 120 through an outlet tube 138.

The injection ring 130 is attached to the inner shell 113 by fasteners 340. In some embodiments, the fasteners 340 are bolts passing through clearance holes 342 formed through the inner shell 113 that engage threaded holes formed in the injection ring 130.

In the embodiment shown in FIG. 3, the high-pressure seals 135, as described above, are disposed between the lift plate 140 and the injection ring 130 in order to seal the high-pressure region 115 for processing when the lift plate 140 is urged against the injection ring 130 to compress the seals 135. The cooling channel 337, as described above, is disposed within the injection ring 130 adjacent to the high-pressure seals 135 to isolate the seals 135 from the heat generated by the heaters 122 which heat the inner shell 113 and the upper shell 112. Since the injection ring 130 is attachable to the inner shell 113 by the fasteners 340, the injection ring 130 is a distinctive component that can be procured separately and attached to the batch processing chamber 100 prior to processing. In this manner, the injection ring 130 may be replaced with a different injection ring 130 having a different set of injection port 134 and outlet ports 136 so that the batch processing chamber 100 can be readily reconfigured for different processes at minimal expense and downtime.

The cassette 150 is disposed on the lift plate 140. The cassette 150 has a top surface 152, a bottom surface 154, and a wall 153. The wall 153 of the cassette 150 has a plurality of substrate storage slots 156. Each substrate storage slot 156 is configured to hold a substrate 155 therein. Each substrate storage slot 156 is evenly spaced along the wall 153 of the cassette 150. For example, in the embodiment shown in FIG. 4, the cassette 150 shows three substrate storage slots 156, each respectively holding a substrate 155. The cassette 150 may have as many as twenty-four or more substrate storage slots.

A substrate transfer port 116 formed through the lower shell 114 is utilized to load the substrates 155 onto the cassette 150. The substrate transfer port 116 has a door 160. The door 160 is configured to cover the substrate transfer port 116 before and after the substrates 155 are loaded. The door 160 may be made from nickel-based steel alloys that exhibit high resistance to corrosion, such as but not limited to HASTELLOY® and may be water-cooled. Vacuum seals 162 are provided to seal the door 160 and the substrate transfer port 116 and thus prevent the leakage of air into the inner chamber 120 when the door 160 is in a closed position.

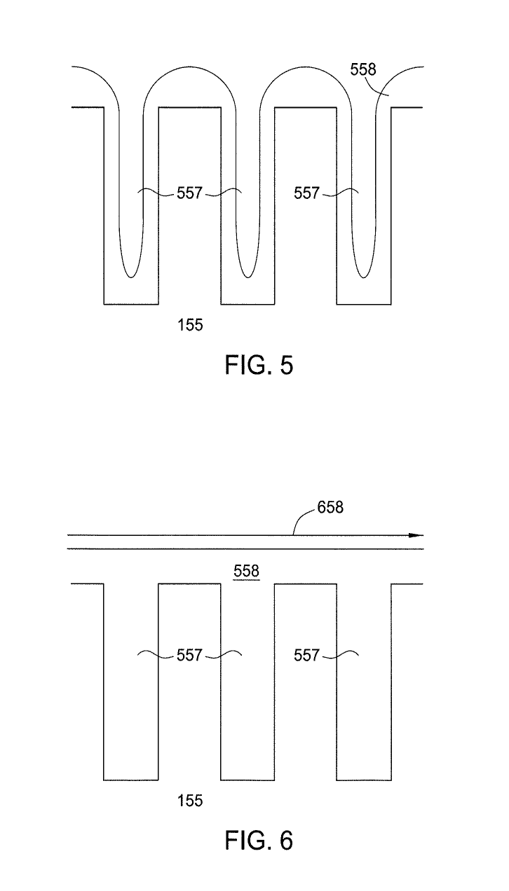

FIGS. 5 and 6 show cross-sectional views of a portion of the substrate 155 before and after processing the substrate 155 in the batch processing chamber 100. The substrate 155 has a number of trenches 557. Before processing in the batch processing chamber 100, the substrate 155 has a flowable material 558 deposited both on the sidewalls and bottom of the trenches 557 as well as on top of the substrate 155. The flowable material 558 may not completely fill the trenches 557 as shown in FIG. 5. The flowable material 558 may be a dielectric material such as silicon carbide (SiC), silicon oxide (SiO), silicon carbon nitride (SiCN), silicon dioxide (SiO₂), silicon oxycarbide (SiOC), silicon carbon oxynitride (SiOCN), silicon oxynitride (SiON) and/or silico nitride (SiN). The flowable material 558 may be deposited using a high-density plasma CVD system, a plasma enhanced CVD system, and/or a sub-atmospheric CVD system, among other systems. Examples of CVD systems capable of forming a flowable layer include the ULTIMA HDP CVD® system and ETERNA CVD® on the PRODUCER® system, both available from Applied Materials, Inc., of Santa Clara, Calif. Other similarly configured CVD systems from other manufacturers may also be utilized.

During processing of the substrate 155 in the batch processing chamber 100, a processing fluid (as shown by arrow 658) is flown across the substrate 155 such that the flowable material 558 flows into and fills the trenches 557, as shown in FIG. 6. The processing fluid may comprise an oxygen-containing and/or nitrogen-containing gas, such as oxygen, steam, water, hydrogen peroxide, and/or ammonia. Alternatively or in addition to the oxygen-containing and/or nitrogen-containing gases, the processing fluid may comprise a silicon-containing gas. The steam may be, for example, dry steam. In one example, the steam is superheated steam. Examples of the silicon-containing gas include organosilicon, tetraalkyl orthosilicate gases and disiloxane. Organosilicon gases include gases of organic compounds having at least one carbon-silicon bond. Tetraalkyl orthosilicate gases include gases consisting of four alkyl groups attached to an SiO₄⁴⁻ ion. More particularly, the one or more gases may be (dimethylsilyl)(trimethylsilyl)methane ((Me)₃SiCH₂SiH(Me)₂), hexamethyldisilane ((Me)₃SiSi(Me)₃), trimethylsilane ((Me)₃SiH), trimethylsilylchloride ((Me)₃SiCl), tetramethylsilane ((Me)₄Si), tetraethoxysilane ((EtO)₄Si), tetramethoxysilane ((MeO)₄Si), tetrakis-(trimethylsilyl)silane ((Me₃Si)₄Si), (dimethylamino)dimethyl-silane ((Me₂N)SiHMe₂) dimethyldiethoxysilane ((EtO)₂Si(Me)₂), dimethyl-dimethoxysilane ((MeO)₂Si(Me)₂), methyltrimethoxysilane ((MeO)₃Si(Me)), dimethoxytetramethyl-disiloxane (((Me)₂Si(OMe))₂O), tris(dimethylamino)silane ((Me₂N)₃SiH), bis(dimethylamino)methylsilane ((Me₂N)₂CH₃SiH), disiloxane ((SiH₃)₂O), and combinations thereof.

Returning to FIG. 1, a remote plasma source (RPS) 190 is connected to the inner chamber 120 by an inlet 195 and configured to generate gaseous radicals that flow through the inlet 195 into the inner chamber 120 to clean the interior of the inner chamber 120 after processing one or more batches of substrates 155. Remote plasma source 190 may be a radio frequency (RF) or very high radio frequency (VHRF) capacitively coupled plasma (CCP) source, an inductively coupled plasma (ICP) source, a microwave induced (MW) plasma source, a DC glow discharge source, an electron cyclotron resonance (ECR) chamber, or a high density plasma (HDP) chamber. The remote plasma source 190 is operatively coupled to one or more sources of gaseous radicals, where the gas may be at least one of disilane, ammonia, hydrogen, nitrogen or an inert gas like argon or helium. The controller 180 controls the generation as well as the distribution of gaseous radicals activated in the remote plasma source 190.

A vacuum pump 125 is connected to the batch processing chamber 100, as shown in FIG. 1. The vacuum pump 125 is configured to evacuate the outer chamber 110 through an exhaust pipe 111, the high-pressure region 115 of the inner chamber 120 through an exhaust pipe 124 and the low-pressure region 117 of the inner chamber 120 through an exhaust pipe 119. The vacuum pump 125 is also connected to an outlet tube 138 connected to the one or more outlets port(s) 136 for removing any fluid from the inner chamber 120. A vent valve 126 is connected to the high-pressure region 115 of the inner chamber 120. The vent valve 126 is configured to vent the inner chamber 120 through a vent pipe 127 so that the pressure is released in the high-pressure region 115 prior to lowering the lift plate 140 and cassette 150. The operation of the vacuum pump 125 and the vent valve 126 is controlled by the controller 180.

The controller 180 controls the operation of the batch processing chamber 100 as well as the remote plasma source 190. The controller 180 is communicatively connected to the fluid source 131 and sensors (not shown) measuring various parameters of the inner chamber 120 by connecting wires 181 and 183 respectively. The controller 180 is communicatively connected to the pump 125 and the vent valve 126 by connecting wires 185 and 187 respectively. The controller 180 is communicatively connected to the lifting mechanism 178 and the remote plasma source 190 by connectors 188 and 189 respectively. The controller 180 includes a central processing unit (CPU) 182, a memory 184, and a support circuit 186. The CPU 182 may be any form of general purpose computer processor that may be used in an industrial setting. The memory 184 may be random access memory, read only memory, floppy, or hard disk drive, or other form of digital storage. The support circuit 186 is conventionally coupled to the CPU 182 and may include cache, clock circuits, input/output systems, power supplies, and the like.

The batch processing chamber 100 advantageously creates isolation between the high-pressure region 115 and the low-pressure region 117 within the inner chamber 120 such that the processing fluid 658 can be flown across the substrate 155 placed in the high-pressure region 115 while maintaining the substrates 155 at a high temperature. During the process, the high-pressure region 115 becomes an annealing chamber, where the flowable material 558 previously deposited on the substrate 155 redistributes to fill the trenches 557 formed in the substrate 155.

The batch processing chamber 100 is utilized to simultaneously process a plurality of substrates 155. Before loading the plurality of substrates 155, the pump 125 is turned on and continuously operated to evacuate the outer chamber 110 and the inner chamber 120 through the exhaust pipes 111 and 119 respectively. Both the outer chamber 110 and inner chamber 120 are evacuated to a vacuum and remain in a vacuum throughout the process. The exhaust pipe 124 connected to the vacuum pump 125 is not yet operational at this time. At the same time, the heaters 122 disposed within the outer chamber 110 are operated to heat the inner chamber 120. The heating element 145 interfaced with the lift plate 140 is also operated at least during a pre-processing stage to heat the cassette 150 such that the substrates 155 being loaded onto the cassette 150 are preheated prior to being elevated into the high-pressure region 115. The door 160 to the substrate transfer port 116 is then opened to load a plurality of substrates 155 on the cassette 150 through the substrate transfer port 116. The substrates 155 have the flowable material 558 deposited thereon as shown in FIG. 5.

After the plurality of substrates 155 are loaded onto the cassette 150, the door 160 to the substrate transfer port 116 is closed. The vacuum seals 162 ensure that there is no leakage of air into the inner chamber 120 once the door 160 is closed. During the pre-processing stage, a fluid may be introduced into the inner chamber 120 through the injection port 134 for wetting the substrates 155. The wetting agent may be a surfactant. The wetting agent provides better interaction between the processing fluid and the substrates 155 disposed in the cassette 150 during processing.

After loading the cassette 150 with substrates 155, the lifting mechanism 178 is utilized to elevate the lift plate 140 and move the cassette 150 disposed thereon to a processing position within the inner shell 113. The lift plate 140 is sealed against the inner shell 113 in order to enclose the high-pressure region 115 within the inner chamber 120 defined within the inner shell 113, thus isolating the high-pressure region 115 from the low-pressure region 117 located below the lift plate 140. During processing of the substrates 155, an environment of the high-pressure region 115 is maintained at a temperature and pressure that maintains the processing fluid within the high-pressure region in a vapor phase. Such pressure and temperature is selected based on the composition of the processing fluid. In one example, high-pressure region 115 is pressurized to a pressure greater than atmosphere, for example greater than about 10 bars. In another example, high-pressure region 115 is pressurized to a pressure from about 10 to about 60 bars, such as from about 20 to about 50 bars. In another example, the high-pressure region 115 is pressurized to a pressure up to about 200 bars. During processing, the high-pressure region 115 is also maintained at a high temperature, for example, a temperature exceeding 225 degrees Celsius (limited by the thermal budget of the substrates 155 disposed on the cassette 150), such as between about 300 degrees Celsius and about 450 degrees Celsius, by the heaters 122 disposed within the outer chamber 110. The heating element 145 interfaced with the lift plate 140 may assist heating of the substrates 155, but may optionally be turned off. The substrates 155 are exposed to a processing fluid 658 introduced through the injection port 134. The processing fluid 658 is removed through the one or more outlet ports 136 using the pump 125. Exposure to the processing fluid 658 at a high pressure while the substrate 155 is maintained at a high temperature causes the flowable material 558 previously deposited on the substrate 155 to redistribute and become firmly packed within the trenches 557 of the substrate 155.

After processing, the vent valve 126 is first operated to vent the inner chamber 120 through the vent pipe 127, thus gradually reducing the pressure inside the high-pressure region 115 to a pressure of about 1 atm. Once the pressure inside the high-pressure region 115 reaches a pressure of 1 atm, the vent valve 126 is closed and the pump 125 is operated to evacuate the high-pressure region 115 through the exhaust pipe 124. The heaters 122 disposed within the outer chamber 110 and/or the heating element 145 interfaced with the lift plate 140 may optionally be turned off to reduce the temperature within the high-pressure region 115, and consequently allow the substrates 155 to begin cooling for substrate transfer. At the same time the injection port 134 is closed. After the high-pressure region 115 is evacuated to a vacuum condition, the lift plate 140 and the cassette 150 disposed thereon are lowered to allow substrate transfer out of the batch processing chamber 100. While the lift plate 140 is lowered, the high-pressure region 115 and the low-pressure region 117 are placed in fluid communication. Since both the high-pressure region 115 and the low-pressure region 117 are now at a vacuum condition, the processed substrates 155 can be removed from the batch processing chamber 100 through the substrate transfer port 116.

After the substrates 155 are removed, the remote plasma source 190 is operated to generate gaseous radicals that flow through the inlet 195 into the inner chamber 120. The gaseous radicals react with impurities present in the inner chamber 120 and form volatile products and byproducts that are removed by the vacuum pump 125 through the one or more outlet ports 136, thus cleaning the inner chamber 120 and preparing the inner chamber 120 for the next batch of substrates 155.

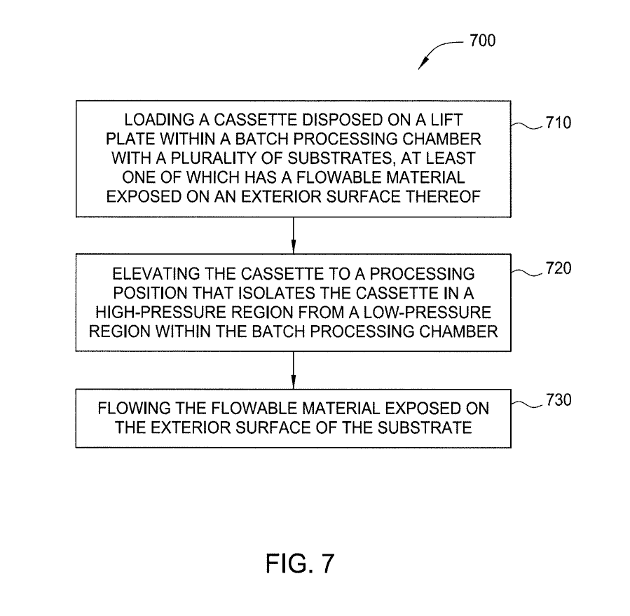

FIG. 7 is a block diagram of a method for processing a plurality of substrates disposed in a batch processing chamber, according to another embodiment of the present disclosure. The method 700 begins at block 710 by loading a cassette disposed on a lift plate with a plurality of substrates. One or more of the substrates has a flowable material exposed on an exterior surface of the substrate. The cassette and the lift plate are disposed in an inner chamber of the batch processing chamber, which is maintained in vacuum. For example and not by limitation, during all stages of operation, the outer chamber disposed within the batch processing chamber and partially surrounding a high-pressure region of the inner chamber is maintained at a vacuum condition. In some embodiments, the substrates are loaded onto the cassette through a substrate transfer port connected to the inner chamber. The cassette has a plurality of substrate storage slots for accommodating the plurality of substrates. Each substrate storage slot on the cassette is indexed to align with the substrate transfer port in order to load a substrate thereon. At the same time, the lift plate and cassette may be pre-heated to start increasing the temperature of the substrates loaded onto the cassette to reduce processing time. Once the cassette is loaded with the substrates, a wetting agent may optionally be introduced into the inner chamber through the injection port to wet the substrates prior to processing in the high-pressure region.

At block 720, once the cassette is loaded with the substrates or otherwise ready for processing, the cassette is elevated to a processing position that isolates the cassette in a high-pressure region from a low-pressure region located within the inner chamber. A lifting mechanism is used to elevate the lift plate and the cassette disposed on the lift plate to the processing position such that the high-pressure region is isolated within the inner chamber.

At block 730, once the high-pressure region has been isolated from the low-pressure region, the vacuum condition with the high-pressure region is replaced with a high-pressure condition. The flowable material disposed on the substrates is redistributed over the substrates by exposing the substrates to a processing fluid, and pressurizing and heating the high-pressure region to a pressure and temperature that maintains a processing fluid within the high-pressure region in a vapor phase. In one example, the high-pressure region is pressurized to a pressure between about 10 and about 60 bars, heating the substrates to a temperature greater than about 225 degrees Celsius. The substrates are heated by maintaining the high-pressure region within the inner chamber at a temperature greater than about 250 degrees Celsius, such as between about 300 degrees Celsius and about 450 degrees Celsius with the heaters disposed within the outer chamber and optionally, the heating elements interfaced with the lift plate that supports the cassette. The processing fluid is introduced into the batch processing chamber through an injection port. In some embodiments, the processing fluid may be steam or water. For example, the steam may be dry steam. In another example, the steam is superheated either before flowing into the chamber or within the chamber, such as by heaters. The processing fluid is removed through one or more outlet ports to the inner chamber. As the substrates are processed, the flowable material exposed on the surface of the substrates redistributes to fill the gaps and trenches formed in the substrates.

After processing, the pressure inside the high-pressure region is reduced to a vacuum. The inner chamber may optionally be cooled down and the injection port is closed. Once the high-pressure region is evacuated to a vacuum condition, the lift plate with the cassette disposed thereon is lowered to allow fluid communication between the high-pressure region and the low-pressure region. The processed substrates, now in vacuum, are removed from the batch processing chamber through the substrate transfer port. After the substrates are removed, the batch processing chamber is cleaned by flowing radicals from a remote plasma source, which react with impurities present in the inner chamber to form volatile products and byproducts that are subsequently pumped out and removed from the inner chamber. The batch processing chamber is thus prepared for processing the next batch of substrates.

The batch processing chamber and the method for processing a plurality of substrates within the batch processing chamber enables processing of the plurality of substrates under high pressure and high temperature. The architecture of the current disclosure advantageously creates isolation within the inner chamber of the batch processing chamber by separating the high-pressure region and the low-pressure region during processing, while the low-pressure region remains in vacuum. The substrates are loaded and unloaded onto a cassette when the isolation is removed. The isolation allows thermal separation between two distinct environments: one for processing in the high-pressure region and the other for loading/unloading the substrates in the low-pressure region. The isolation also prevents thermal inconsistencies among the components of the chamber by keeping the high-pressure region enclosed during processing.

The outer chamber, disposed around the high-pressure region of the inner chamber and continually maintained in vacuum, additionally functions as a safety containment between the processing environment of the high-pressure region inside the inner chamber and the atmosphere outside the batch processing chamber in order to prevent any leakage of air into the processing environment or loss of processing fluid into the atmosphere outside the chamber. Further, since the outer chamber is maintained in vacuum and isolated from the atmosphere outside the batch processing chamber, the outer chamber offers flexibility in the choice of heaters that are installed in the outer chamber and configured to heat the inner chamber. Thus, heaters that work more effectively under vacuum conditions may be utilized.

The batch processing chamber described above additionally offers the flexibility of being operable as either a standalone process chamber or one that is docked to the factory interface in a cluster tool or in-situ as part of a process chamber. This ensures a cleanroom level environment that can be maintained for processing the substrates.

While the foregoing is directed to particular embodiments of the present disclosure, it is to be understood that these embodiments are merely illustrative of the principles and applications of the present invention. It is therefore to be understood that numerous modifications may be made to the illustrative embodiments to arrive at other embodiments without departing from the spirit and scope of the present inventions, as defined by the appended claims.

What is claimed is:

1. A batch processing chamber comprising:
a lower shell;
a substrate transfer port formed through the lower shell;
an upper shell disposed on the lower shell;
an inner shell disposed within the upper shell, the inner shell and upper shell bounding an outer chamber, the inner shell and the lower shell bounding an inner chamber that is isolated from the outer chamber;
a heater operational to heat the inner shell;
a lift plate moveably disposed within the lower shell, wherein the lift plate, when in a raised position, sealingly separates the inner chamber into high-pressure and low-pressure regions, the high-pressure region bounded by the lift plate and the inner shell;
a cassette disposed on the lift plate and configured to hold a plurality of substrates; and
an injection port configured to introduce a fluid into the inner chamber.

2. The batch processing chamber of claim 1, wherein the outer chamber is fluidly isolated from the inner chamber.

3. The batch processing chamber of claim 2, wherein the heater is disposed in the outer chamber.

4. The batch processing chamber of claim 1, wherein the lift plate, when in the raised position, seals the cassette in the high-pressure region.

5. The batch processing chamber of claim 4, wherein the lift plate, when in a lowered position, allows fluid communication between the high-pressure region and the low-pressure region.

6. The batch processing chamber of claim 1, wherein the lift plate, when in a raised position, contacts a high-pressure seal that sealingly separates the inner chamber into high-pressure and low-pressure regions.

7. The batch processing chamber of claim 6 further comprising:
a cooling channel disposed adjacent to the high-pressure seal, the cooling channel disposed between the high-pressure seal and the heater.

8. The batch processing chamber of claim 1 further comprising:
one or more outlet ports facing the injection port across the inner chamber.

9. The batch processing chamber of claim 1 further comprising:
an injection ring removably coupled to a bottom surface of the inner shell, the injection ring having the injection port disposed therein.

10. The batch processing chamber of claim 9 further comprising:
a high-pressure seal configured to seal the injection ring to the lift plate when the lift plate is in a raised position.

11. The batch processing chamber of claim 10 further comprising:
a cooling channel disposed in the injection ring between the high-pressure seal and the inner shell.

12. The batch processing chamber of claim 9 further comprising:
one or more outlet ports formed through the injection ring facing the injection port across the inner chamber.

13. The batch processing chamber of claim 1 further comprising:
a remote plasma source fluidly coupled to the inner chamber.

14. The batch processing chamber of claim 1 further comprising:
a heating element interfaced with the lift plate.

15. A batch processing chamber comprising:
a lower shell;
a substrate transfer port formed through the lower shell;
a bottom plate coupled to a bottom surface of the lower shell;
an upper shell disposed on the lower shell;
an inner shell disposed within the upper shell, the inner shell bounding a portion of an inner chamber having a high-pressure region and a low-pressure region;
an outer chamber bounded by the inner shell and the upper shell, the outer chamber isolated from the inner chamber;
one or more heaters disposed within the outer chamber and operational to heat the inner shell;
a lift plate moveably disposed within the lower shell, the lift plate configured to be raised to seal the high-pressure region and lowered to allow fluid communication between the high-pressure region and the low-pressure region;
a heating element coupled to the lift plate;
a cassette disposed on the lift plate and configured to hold a plurality of substrates;
an injection ring removably coupled to a bottom surface of the inner shell;
an injection port disposed within the injection ring and configured to introduce a fluid into the inner chamber;
a high-pressure seal configured to couple the injection ring to the lift plate in the high-pressure region;
a cooling channel disposed adjacent to the high-pressure seal;
one or more outlet ports formed through the injection ring facing the injection port across the inner chamber; and
a remote plasma source coupled to the inner chamber.

16. A method of processing a plurality of substrates disposed in a batch processing chamber, comprising:
loading a cassette disposed on a lift plate with a plurality of substrates, the cassette and lift plate disposed in an inner chamber of the batch processing chamber, at least a first substrate of the plurality of substrates having a flowable material exposed on an exterior surface thereof;
elevating the cassette to a processing position that isolates the cassette in a high-pressure region of the inner chamber from a low-pressure region of the inner chamber; and
flowing the flowable material exposed on the exterior surface of the first substrate, wherein flowing further comprises:
exposing the first substrate to a processing fluid at a temperature and pressure that maintains the processing fluid in a vapor phase while within the high-pressure region.

17. The method of claim 16, wherein exposing the first substrate to a processing fluid comprises:
exposing the first substrate to steam or water.

18. The method of claim 16 further comprising:
exposing the first substrate to a wetting agent within the inner chamber prior to raising the lift plate.

19. The method of claim 16 further comprising:
maintaining a vacuum in an outer chamber that partially surrounds the high-pressure region of the inner chamber.

20. The method of claim 16, further comprising:
cleaning the inner chamber by flowing radicals from a remote plasma source.
